(19) United States
(12) Patent Application Publication
(10) Pub. No.: US 2020/0083582 A1
(43) Pub. Date: Mar. 12, 2020

(54) HIGH FREQUENCY CIRCUIT WITH RADAR ABSORBING MATERIAL TERMINATION COMPONENT AND RELATED METHODS

(71) Applicant: XCERRA CORPORATION, Norwood, MA (US)

(72) Inventors: Jason Mroczkowski, St. Paul, MN (US); Nadia Steckler, St. Paul, MN (US); James Hattis, St. Paul, MN (US); Aaren Lonks, St. Paul, MN (US)

(73) Assignee: XCERRA CORPORATION, Norwood, MA (US)

(21) Appl. No.: 16/563,729

(22) Filed: Sep. 6, 2019

Related U.S. Application Data
(60) Provisional application No. 62/728,427, filed on Sep. 7, 2018.

(51) Int. Cl. H01P 1/26; H01L 23/66; H01L 23/495; H01P 5/22

(52) U.S. Cl. CPC H01P 1/26; H01L 23/66; G01R 1/045; H01P 5/22; H01L 2223/6627; H01L 23/49541

(57) ABSTRACT

A high speed circuit assembly includes a high speed circuit including at least one transmission line extending to a transmission line end, and radar absorbing material disposed adjacent the transmission line.

### RELATED APPLICATION

This application claims priority to U.S. Provisional Application No. 62/728,427 that was filed on Sep. 7, 2018. The entire content of the application referenced above is hereby incorporated by reference herein.

### TECHNICAL FIELD

High frequency circuit assemblies and related methods.

### TECHNICAL BACKGROUND

Test contactors are used on printed circuit boards to test various parameters and/or components of semiconductor devices. Electronic devices have become smaller yet more powerful, resulting crowded and complex circuit boards. For example, modern automobiles are using RADAR equipment for collision avoidance, parking assist, automated driving, cruise control, etc. The radio frequencies used in such systems are typically 76-81 GHz (W-band). Also, the radio frequencies used for Wi-Fi applications are in the range of 56-64 GHz. The upcoming 5G cellular/cellular backhaul market uses frequencies in the sub 6 GHz, as well as 24-30 GHz, 37-48 GHz, and 64-71 GHz bands. Furthermore, semiconductor devices include antenna in package to minimize the footprint of the overall wireless chipset. Circuits that operate at these frequencies need to have terminations. At high frequency, the resistive termination device typically are a thin film process and surface mount devices. However, standard surface mount components tend to have parasitic impedance at higher frequencies. In addition, there are limits on where thin film components are used. The thin film process is expensive and difficult to implement in certain devices, such as a test contactor assembly.

What is needed is a way to effectively terminate high frequency circuits.

### SUMMARY

What is described herein is the implementation of radar absorbing material for use as an electronic termination component in high frequency circuits.

A high speed circuit assembly includes a high speed circuit including at least one transmission line extending to a transmission line end, and radar absorbing in contact with the at least one transmission line.

In one or more embodiments, the high speed circuit is a lead frame.

In one or more embodiments the high speed circuit assembly further includes a frame assembly disposed near the lead frame, and the frame assembly is a ground reference for the lead frame.

In one or more embodiments the high speed circuit assembly further includes a frame assembly disposed near the lead frame, and the frame assembly is a power supply.

In one or more embodiments, the radar absorbing material is disposed between the frame assembly and the transmission line end.

In one or more embodiments, the frame assembly includes a recess, and the radar absorbing material is disposed at least partially within the recess.

In one or more embodiments, the radar absorbing material is an attenuator for the high speed circuit.

In one or more embodiments, the high speed circuit includes at least one ring coupler.

In one or more embodiments, the radar absorbing material absorbs signals in a range of 1 GHz-110 GHz.

In one or more embodiments, the radar absorbing material absorbs signals in the range of 18 GHz-40 GHz.

In one or more embodiments, the radar absorbing material absorbs signals in the range of 40 GHz-80 GHz.

In one or more embodiments, the radar absorbing material absorbs signals in the range of 6 GHz-35 GHz.

In one or more embodiments, the radar absorbing material absorbs signals in the range of 1 GHz-30 GHz.

In one or more embodiments, the radar absorbing material absorbs signals in the range of 1 GHz-4 GHz.

A method includes applying a high frequency signal to a high speed circuit assembly, where the high speed circuit includes at least one transmission line extending to a transmission line end, and radar absorbing material in contact with the at least one transmission line. The method further includes terminating the high frequency signal with the radar absorbing material.

A test socket assembly including a frame assembly having a socket opening sized and configured to receive a device under test therein, and a high speed circuit including at least one transmission line extending to a transmission line end. The high speed circuit includes a lead frame assembly disposed adjacent to the frame assembly. The test socket assembly further includes radar absorbing material in contact with the at least one transmission line. The radar absorbing material terminates the at least one transmission line.

In some embodiments, a high speed circuit assembly including a high speed circuit including at least one transmission line including a contactor signal probe and extending to a transmission line end, and a radar absorbing material in contact with the at least one transmission line and a radar absorbing structure in contact with the contactor signal probe, the radar absorbing material terminates the at least one transmission line.

In some embodiments, a high speed circuit assembly including a high speed circuit including at least one transmission line extending to a transmission line end, and a radar absorbing material in close proximity with the at least one transmission line, the radar absorbing material terminates the at least one transmission line.

In some embodiments, a high speed circuit assembly including a high speed circuit including at least one transmission line including a contactor signal probe and extending to a transmission line end, and a radar absorbing material in close proximity with the at least one transmission line and a radar absorbing structure in close proximity with the contactor signal probe, the radar absorbing material terminates the at least one transmission line.

In some embodiments, a high speed circuit assembly including a high speed circuit including at least one transmission line including a contactor signal probe and extending to a transmission line end, and a radar absorbing structure in contact with the contactor signal probe, a radar absorbing material terminates the at least one transmission line.

In some embodiments, a high speed circuit assembly including a high speed circuit including at least one transmission line including a contactor signal probe and extending to a transmission line end, and a radar absorbing structure in close proximity with the contactor signal probe, a radar absorbing material terminates the at least one transmission line.

In some embodiments, a high speed circuit assembly including a high speed circuit including at least one transmission line including a contactor signal probe, a radar absorbing structure in contact with the contactor signal probe, the radar absorbing structure terminates the at least one transmission line.

In some embodiments, a high speed circuit assembly including a high speed circuit including at least one transmission line extending to a transmission line end, a radar absorbing material in close proximity with the at least one transmission line, the radar absorbing material terminates the at least one transmission line.

In some embodiments, a high speed circuit assembly including a high speed circuit including at least one transmission line including a contactor signal probe and extending to a transmission line end, and a radar absorbing material in close proximity with the at least one transmission line and a radar absorbing structure in close proximity with the contactor signal probe, the radar absorbing material terminates the at least one transmission line.

In some embodiments, a high speed circuit assembly including a high speed circuit including at least one transmission line including a contactor signal probe, and a radar absorbing structure in contact with the contactor signal probe.

In some embodiments, a high speed circuit assembly including a high speed circuit including at least one transmission line including a contactor signal probe, and a radar absorbing structure in close proximity with the contactor signal probe.

These and other embodiments, aspects, advantages, and features of the present invention will be set forth in part in the description which follows, and will become apparent to those skilled in the art by reference to the following description of the invention and referenced drawings or by practice of the invention. The aspects, advantages, and features of the invention are realized and attained by means of the instrumentalities, procedures, and combinations particularly pointed out in the appended claims and their equivalents.

### BRIEF DESCRIPTION OF THE FIGURES

FIG. 1 illustrates a perspective view of a test contactor assembly as constructed in one or more embodiments.

FIG. 2 illustrates a perspective view of a test contactor assembly as constructed in one or more embodiments.

FIG. 3 illustrates a perspective view of a portion of a high frequency circuit assembly as constructed in one or more embodiments.

FIG. 4 illustrates a perspective view of a portion of a high frequency circuit assembly as constructed in one or more embodiments.

FIG. 5 illustrates a top view of a high frequency circuit assembly as constructed in one or more embodiments.

FIG. 6 illustrates a top view of a high frequency circuit assembly as constructed in one or more embodiments.

FIG. 7 illustrates a contactor assembly including a contact signal probe and a radar absorbing structure as constructed in one or more embodiments.

FIG. 8 illustrates a contactor assembly having two test sites including a first test site and a second test site and the radar absorbing structure as constructed in one or more embodiments.

FIG. 9 illustrates the contactor assembly having two sites including the first test site and the second test site as constructed in one or more embodiments.

FIG. 10 illustrates a contactor assembly including a die and the radar absorbing structure and the contactor signal probe as constructed in one or more embodiments.

### DETAILED DESCRIPTION

The following detailed description includes references to the accompanying drawings, which form a part of the detailed description. The drawings show, by way of illustration, specific embodiments in which the apparatus may be practiced. These embodiments, which are also referred to herein as “examples” or “options,” are described in enough detail to enable those skilled in the art to practice the present embodiments. The embodiments may be combined, other embodiments may be utilized or structural or logical changes may be made without departing from the scope of the invention. The following detailed description is, therefore, not to be taken in a limiting sense and the scope of the invention is defined by the appended claims and their legal equivalents.

In this document, the terms “a” or “an” are used to include one or more than one, and the term “or” is used to refer to a nonexclusive “or” unless otherwise indicated. In addition, it is to be understood that the phraseology or terminology employed herein, and not otherwise defined, is for the purpose of description only and not of limitation.

A device is described herein including the implementation of radar absorbing material for use as an electronic termination component in high frequency circuits. In one or more embodiments, the device includes a test socket assembly 100.

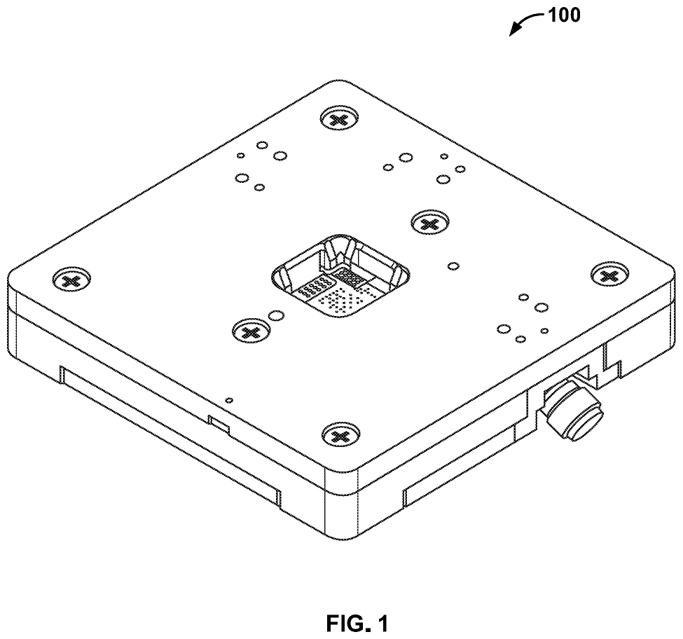

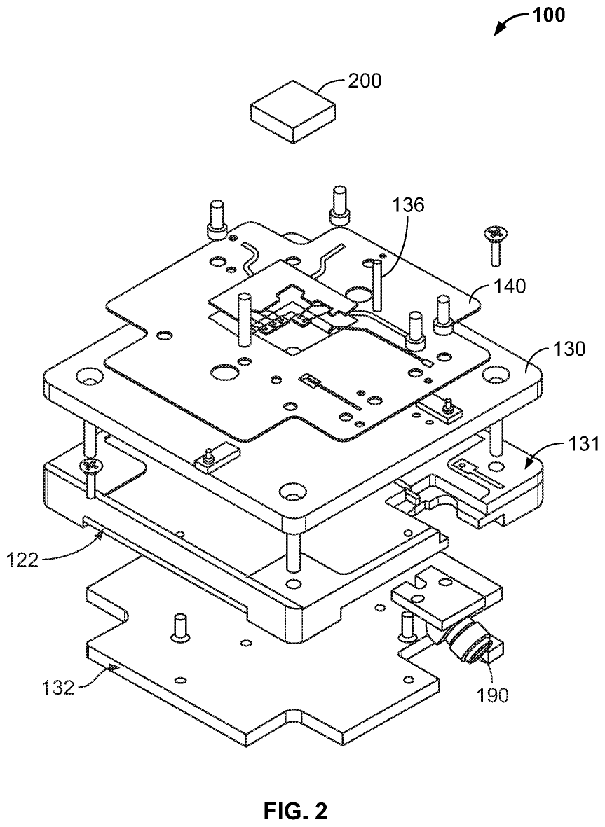

FIGS. 1-2 illustrate a test socket assembly 100, such as an mmWave contactor, including a high frequency circuit assembly. In one or more embodiments, the high frequency circuit assembly operates at a frequency in the range of 1 GHz-110 GHz. In one or more embodiments, the high frequency circuit assembly operates at a frequency of about 18 GHz-40 GHz. In one or more embodiments, the high frequency circuit assembly operates at a frequency of about 40 GHz-80 GHz. In one or more embodiments, the high frequency circuit assembly operates at a frequency of about 6 GHz-35 GHz. In one or more embodiments, the high frequency circuit assembly operates at a frequency of about 1 GHz-30 GHz. In one or more embodiments, the high frequency circuit assembly operates at a frequency of about 1 GHz-4 GHz.

In one or more embodiments, the test socket assembly 100 is used with a device under test (DUT) 200, and can communicate via compliant interconnects with the device under test 200. The test socket assembly 100 allows direct communication between test hardware and the device under test while maintaining a contacted spring probe interface for remaining standard inputs and outputs on a BGA/QFN/WLCSP, or any other packaging technology. The test socket assembly 100 can include compliant interconnects and compliant or static lead frames and other features as described in U.S. Pat. No. 10,037,933, which is incorporated herein by reference in its entirety.

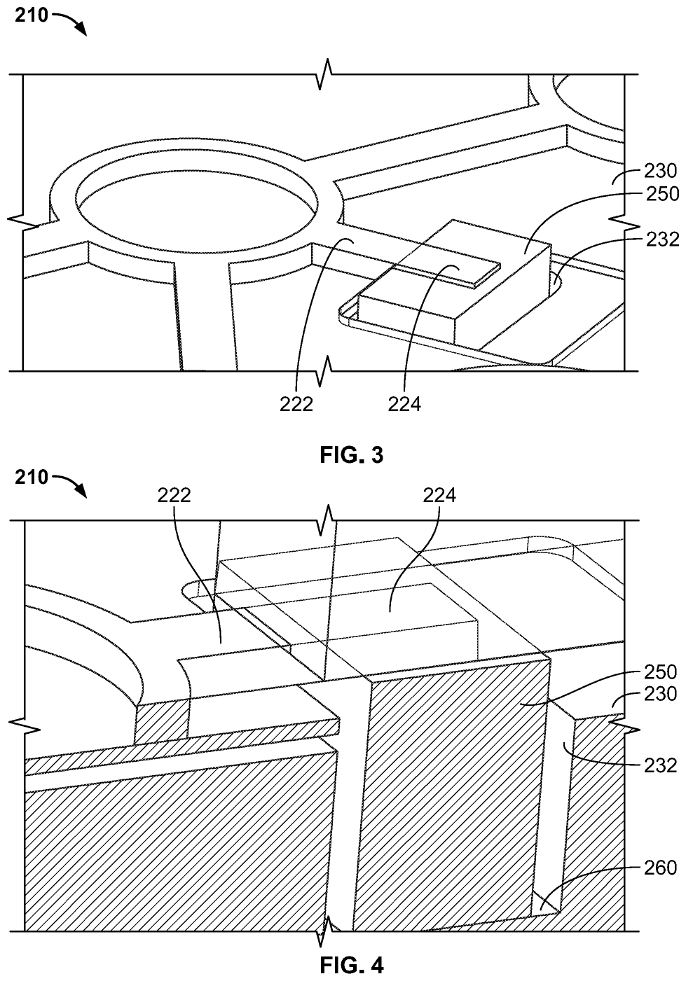

In one or more embodiments the test socket assembly 100 includes frame assembly 130, a high speed circuit assembly 210 (FIG. 3-6) such as a lead frame assembly 140, a contactor body 131, compliant interconnects, a printed circuit board 132, probe retainer plate 122, and one or more dowel pins 136, as shown in FIG. 2, which shows an exploded view of the test socket assembly 100 of FIG. 1. There is also substrate material which is used to align and hold the lead frame assembly 140 together.

The test socket assembly 100 is used with a device under test (DUT) 200. A socket opening within the frame assembly 130 receives the DUT 200 therein and assists in aligning the DUT 200 with the test socket assembly 100. The socket opening is sized and configured to receive the DUT 200 therein.

The test socket assembly 100 includes a high speed lead frame assembly 140 and one or more compliant interconnects, and at least one return. The spring return provides force back up into the assembly 100 and supports the lead frame assembly 140. The lead frame assembly 140 is disposed adjacent to the frame assembly 130, and is electrically coupled with the one or more compliant interconnects, which are also disposed within the frame assembly 130. The lead frame assembly 140 is sandwiched between the frame assembly 130 and the contactor body 131.

In one or more embodiments, as shown in FIGS. 3-6, the high speed circuit assembly 210 includes a high speed circuit 220 including at least one transmission line 222 extending to a transmission line end 224. The high speed circuit assembly 210 can be implemented in the test socket assembly as discussed above, or any other high speed device.

In one or more embodiments, the high speed circuit 220 has an operating frequency and an operating frequency wavelength. In one or more embodiments, the at least one transmission line 222 is defined by a length. In one or more embodiments, the length of the at least one transmission line 222 is greater than 0.1*operating frequency wavelength. The relation between frequency and wavelength is:

wavelength(λ)=Speed of light(c)/[√ε*Frequency(f)]

where √ε is the dielectric constant of the material used in the transmission line structure (microstrip, coplanar waveguide, stripline, slotted line, etc.

In one or more embodiments, the at least one transmission line 222 includes signal termination at the transmission line end 224. In one or more embodiments, radar absorbing material is disposed at the transmission line end 224. In one or more embodiments, the radar absorbing material is in contact with the at least one transmission line 222. In one or more embodiments, the radar absorbing material is in close proximity with the transmission line 222. Close proximity is a measure of distance on the order of microns or tens of microns. In some embodiments, close proximity is between about one micron and 100 microns. In some embodiments, close proximity is between about one micron and about 80 microns. In some embodiments, close proximity is between about one micron and about 60 microns. In some embodiments, close proximity is between about one micron and about 40 microns. In some embodiments, close proximity is between about one micron and about 20 microns. In some embodiments, close proximity is between about one micron and about 10 microns. In some embodiments, close proximity is between about 5 micron and about 10 microns. In one or more embodiments, the radar absorbing material is used to terminate the signal of the transmission line 222. In some embodiments, the transmission line 222 is not terminated by the radar absorbing material.

The radar absorbing material (RAM) is a material which has been specially designed and shaped to absorb incident RF radiation (also known as non-ionising radiation), as effectively as possible, from as many incident directions as possible. The more effective the RAM, the lower the resulting level of reflected RF radiation. The radar absorbing material 250 includes a cut section of material, sized to achieve an effective termination of the transmission line 222.

In one or more embodiments, the radar absorbing material absorbs signals in a range of 1 GHz-110 GHz. In one or more embodiments, the radar absorbing material absorbs signals in the range of 18 GHz-40 GHz. In one or more embodiments, the radar absorbing material absorbs signals in the range of 40 GHz-80 GHz. In one or more embodiments, the radar absorbing material absorbs signals in the range of 6 GHz-35 GHz. In one or more embodiments, the radar absorbing material absorbs signals in the range of 1 GHz-30 GHz. In one or more embodiments, the radar absorbing material absorbs signals in the range of 1 GHz-4 GHz.

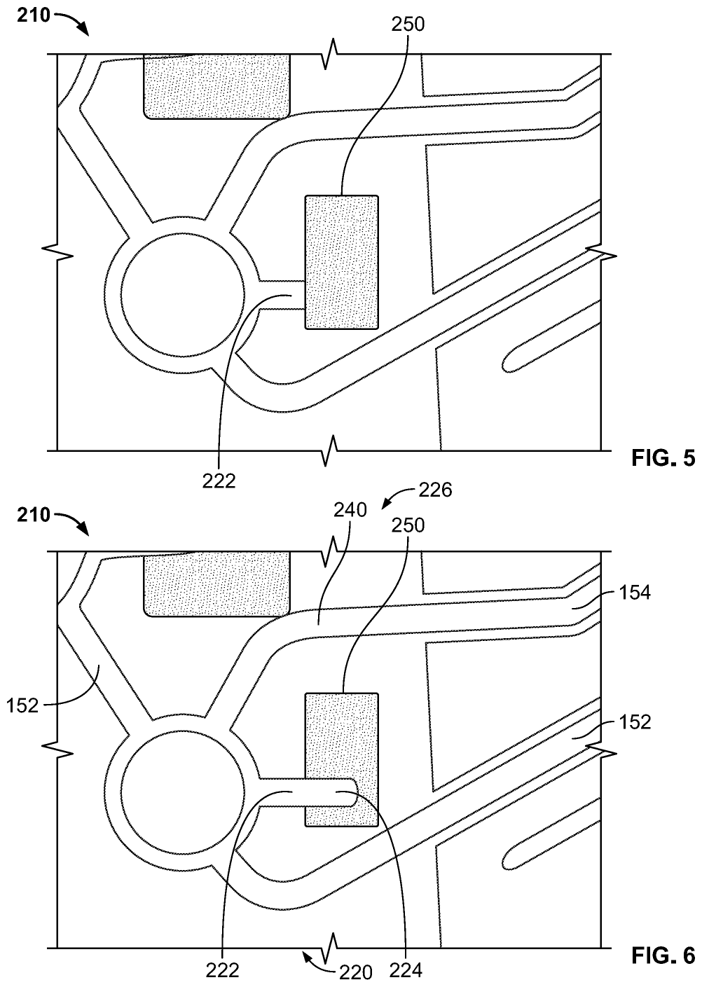

In one or more embodiments the high speed circuit assembly 210 further includes a frame assembly 230 disposed near the lead frame 240, and the frame assembly 230 is a ground reference or a ground plane 260 for the lead frame 240. In one or more embodiments the high speed circuit assembly 210 further includes a frame assembly 230 disposed near the lead frame 240, and the frame assembly 230 is a power supply. In one or more embodiments, the radar absorbing material 250 is disposed between the frame assembly 230 and the transmission line end 224. In one or more embodiments, the frame assembly 230 includes a recess 232, and the radar absorbing material 250 is disposed at least partially within the recess 232. In one or more embodiments, the radar absorbing material 250 is an attenuator for the high speed circuit 220. For example, the radar absorbing material 250 can be disposed on top of the transmission line 222, as shown in FIG. 5.

In one or more embodiments, the high speed circuit 220 is a lead frame 240 with a ring coupler 226, as shown in FIGS. 3, 4, and 6, which show the lead frame 240 in greater detail. The lead frame 240 can also include a hybrid ring coupler including at least one ring, at least one input 152, at least two outputs 154, where the hybrid ring coupler 150 forms part of the lead frame 240. In one or more embodiments, at least one of the at least two outputs include a device contact portion to contact the DUT 200 when the DUT is disposed within the socket opening. The hybrid ring coupler 150 further includes a terminator, such as isolation port with an absorber. In one or more embodiments, the lead frame assembly 240 includes a loop back trace electrically coupled between the at least one input and the at least two outputs.

A method includes applying a high frequency signal to a high speed circuit assembly, where the high speed circuit includes at least one transmission line extending to a transmission line end, and radar absorbing material in contact with the at least one transmission line. The method further includes terminating the high frequency signal with the radar absorbing material.

The high speed circuit assembly includes an effective and inexpensive solution to termination of transmission lines that would be otherwise prohibitively expensive or difficult to terminate with conventional terminators, particularly at high frequencies. The test socket assembly described and shown herein is a test socket that is compatible with semiconductor back-end manufacturing, yet is capable in operating at the W-band frequencies and includes a high speed circuit with radar absorbing material as a terminator of a transmission line end. Optionally, the test socket assembly includes a hybrid ring coupler embedded within the contactor as a splitter, and including the radar absorbing material terminator. The hybrid ring coupler allows for the large bandwidth and high isolation when splitting a signal from one line to two lines and can be used for splitting high frequency signals.

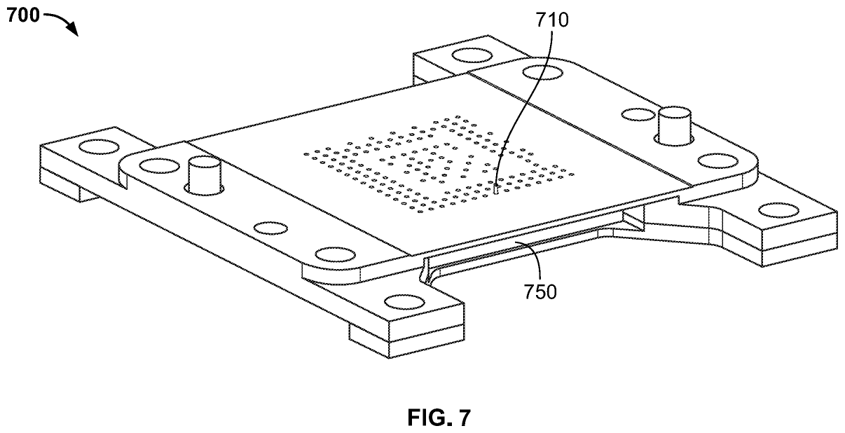

FIG. 7 illustrates a contactor assembly 700 including a contactor signal probe 710 and the radar absorbing structure 750 as constructed in one or more embodiments. The contactor signal probe 710 is a transmission line suitable for use in contacting pins or ports in a device under test such as an integrated circuit. In some embodiments, the radar absorbing structure 750 is formed from the radar absorbing material described above. In some embodiments, the radar absorbing structure 750 is a structure, such as a rectangular block, having holes through which the contactor signal probe 710 passes. In some embodiments, the contactor signal probe 710 is in contact with the radar absorbing structure 750. In some embodiments, the contactor signal probe 710 is in contact with the radar absorbing structure 750, and the transmission line 222 (shown in FIG. 3-6) is in contact with the radar absorbing material 250. In some embodiments, the contactor signal probe 710 is in close proximity with the radar absorbing structure 750 and does not contact the radar absorbing structure 750. In some embodiments, the contactor signal probe 710 is in close proximity with the radar absorbing structure 750, and the transmission line 222 is in close proximity with the radar absorbing material 250. A radar absorbing material suitable use in connection with the fabrication of the radar absorbing structure 750 includes a rigid magnetized epoxy loaded stock. In operation, the contactor signal probe 710 is a transmission line and couples a signal from a device under test, such as an integrated circuit, to the radar absorbing structure 750. The radar absorbing structure 750 terminates the contactor signal probe 710 for a signal originating at the device under test.

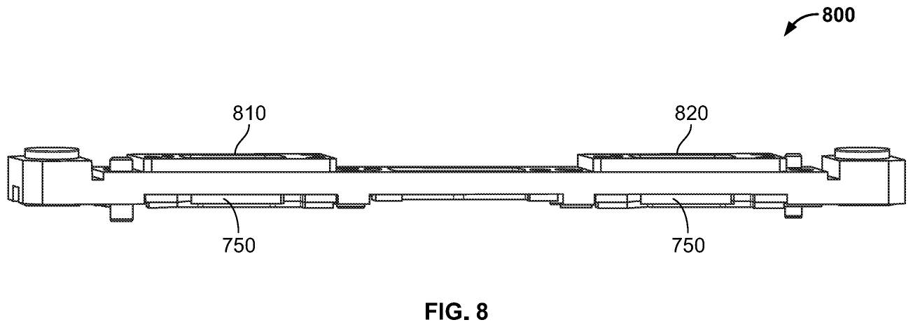

FIG. 8 illustrates a contactor assembly 800 having two test sites including a first test site 810 and a second test site 820 and the radar absorbing structure 750 as constructed in one or more embodiments.

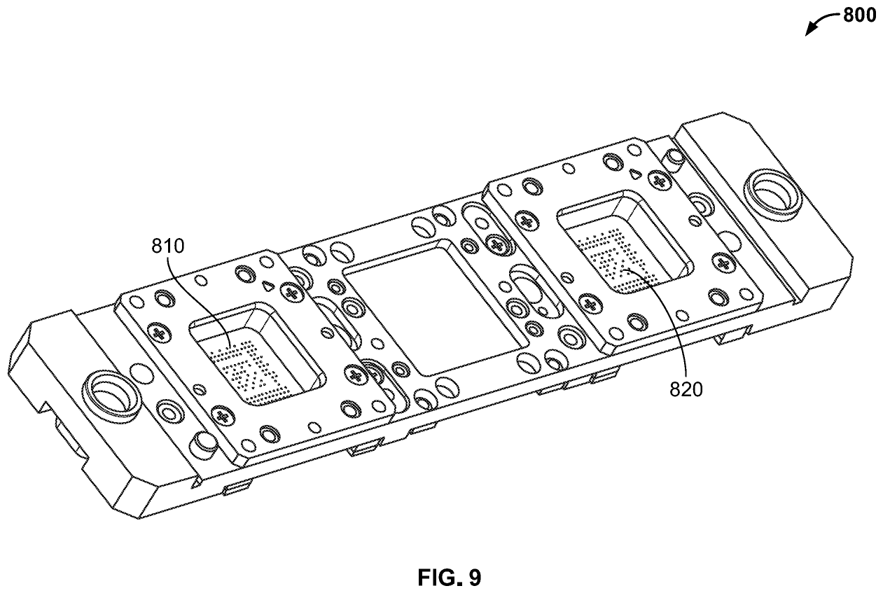

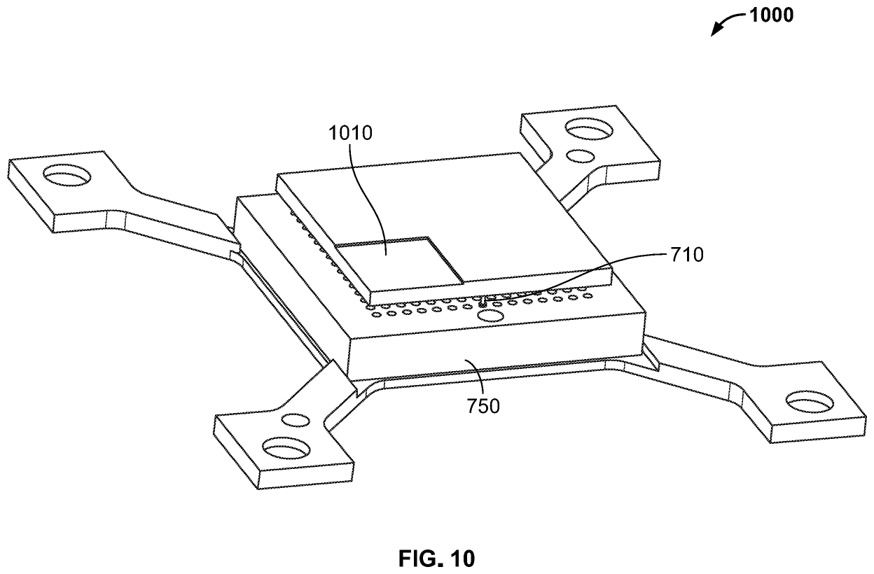

FIG. 9 illustrates the contactor assembly 800 having two sites including the first test site 810 and the second test site 820 as constructed in one or more embodiments.

FIG. 10 illustrates a contactor assembly 1000 including a die 1010 and the radar absorbing structure 750 and the contactor signal probe 710 as constructed in one or more embodiments. The die 1010 includes an integrated circuit. In some embodiments, the contactor signal probe 710 is in contact with the radar absorbing structure 750. In some embodiments, the contactor signal probe 710 is in close proximity with the radar absorbing structure 750 and is not in contact with the radar absorbing structure 750. In operation, the contactor signal probe 710 couples a test signal to the die 1010 and the integrated circuit included on the die 1010.

It is to be understood that the above description is intended to be illustrative, and not restrictive. Many other embodiments will be apparent to those of skill in the art upon reading and understanding the above description. It should be noted that embodiments discussed in different portions of the description or referred to in different drawings can be combined to form additional embodiments of the present application. The scope should, therefore, be determined with reference to the appended claims, along with the full scope of equivalents to which such claims are entitled.

1. A high speed circuit assembly comprising:
a high speed circuit including at least one transmission line extending to a transmission line end; and
radar absorbing material in contact with or in close proximity with the at least one transmission line, the radar absorbing material terminates the at least one transmission line.

2. The high speed circuit assembly as recited in claim 1, wherein the high speed circuit is a lead frame.

3. The high speed circuit assembly as recited in claim 2, further comprising a frame assembly disposed near the lead frame, and the frame assembly is a ground reference for the lead frame.

4. The high speed circuit assembly as recited in claim 2, further comprising a frame assembly disposed near the lead frame, and the frame assembly is a power supply.

5. The high speed circuit assembly as recited in claim 4, wherein the radar absorbing material is disposed between the frame assembly and the transmission line end.

6. The high speed circuit assembly as recited claim 5, wherein the frame assembly includes a recess, and the radar absorbing material is disposed at least partially within the recess.

7. The high speed circuit assembly as recited in claim 1, wherein the radar absorbing material is an attenuator for the high speed circuit.

8. The high speed circuit assembly as recited in claim 1, wherein the high speed circuit includes at least one ring coupler.

9. The high speed circuit assembly as recited in claim 1, wherein the high speed circuit has an operating frequency and an operating frequency wavelength, and the at least one transmission line is defined by a length, and the length of the at least one transmission line is greater than 0.1*operating frequency wavelength.

10. A method comprising:
applying a high frequency signal to a high speed circuit assembly, the high speed circuit including at least one transmission line extending to a transmission line end, and radar absorbing material in contact with or in close proximity to the at least one transmission line; and
terminating the high frequency signal with the radar absorbing material.

11. A high speed circuit assembly comprising:
a high speed circuit including at least one transmission line including a contactor signal probe; and
a radar absorbing structure in contact with or in close proximity with the contactor signal probe.

12. The high speed circuit assembly of claim 11, wherein a radar absorbing material terminates the at least one transmission line.

13. The high speed circuit assembly of claim 11, wherein the radar absorbing structure terminates the contactor signal probe.

14. A high speed circuit assembly comprising:
a high speed circuit including at least one transmission line including a contactor signal probe and extending to a transmission line end; and
a radar absorbing material in contact with or in close proximity with the at least one transmission line and a radar absorbing structure in contact with or in close proximity with the contactor signal probe.

15. The high speed circuit assembly of claim 14, wherein the radar absorbing material terminates the at least one transmission line.
